(19) United States
(12) Patent Application Publication
(10) Pub. No.: US 2023/0097254 A1
(43) Pub. Date: Mar. 30, 2023

(54) METHOD OF MANUFACTURING FLUORESCENT SUBSTANCE

(71) Applicant: ROOTS Co., Ltd., Incheon (KR)

(72) Inventors: Sung Yoon LEE, Incheon (KR); Soon Min KIM, Incheon (KR); Jong Woo HA, Seoul (KR)

(73) Assignee: ROOTS Co., Ltd., Incheon (KR)

(21) Appl. No.: 17/868,840

(22) Filed: Jul. 20, 2022

(30) Foreign Application Priority Data
Sep. 24, 2021 (KR) 10-2021-0126287

(51) Int. Cl. H01L 51/00; C09J 191/06

(52) U.S. Cl. CPC H01L 51/0012; C09J 191/06

(57) ABSTRACT

A method of manufacturing a fluorescent substance may include forming dicing trenches on one surface of a fluorescent substance wafer along grid-type dicing lines, filling the dicing trench with an adhesive material having fluidity, curing the adhesive material, reducing a thickness of a surface opposite to the one surface on which the dicing trenches are formed to make an integrated form of a plurality of individual fluorescent substances, which are divided along the dicing lines, with the adhesive material connecting therebetween, and removing the adhesive material to remain only the divided individual fluorescent substances.

### CROSS-REFERENCE TO RELATED APPLICATION

This application claims priority to and the benefit of Korean Patent Application No. 10-2021-0126287, filed on Sep. 24, 2021, the disclosure of which is incorporated herein by reference in its entirety.

### BACKGROUND

### 1. Field of the Invention

The present invention relates to a method of manufacturing a fluorescent substance. More particularly, the present invention relates to a method of manufacturing a fluorescent substance as a color conversion member for changing a wavelength of light emitted from a light-emitting diode (LED) chip.

### 2. Discussion of Related Art

Korean Patent Registration No. 2243674 discloses a process of manufacturing a color conversion member in the form of a thin and wide wafer and then dividing the color conversion member into a plurality small fluorescent substances as a post-processing process. During a process of dividing a wafer into tiny fluorescent substances, that is, dicing or grinding, there may be a possibility that the wafer is damaged or some of small fluorescent substance chips are away from a workbench.

In particular, when a process of directly dividing a wafer with a dicing blade shown in FIG. 8 is applied, the above problem may appear larger. During the process, the wafer is placed on a ring-shaped wafer ring and a disc-shaped ultraviolet (UV) tape fixed to an inside of the wafer ring. An adhesive material is applied on an upper surface of the UV tape, and thus the wafer may be fixed. A grinding operation is performed on a wafer having a thickness of approximately 1.5 mm first to allow the wafer to have a thickness ranging from 0.1 to 0.2 mm, and then the wafer is cut out in a grid shape using a dicing blade. Fluorescent particles of the wafer are crushed and cut by the dicing blade, and in this process, a chipping phenomenon, in which a side surface of the fluorescent substance is unevenly crushed, occurs. In addition, the fluorescent substance may not overcome a rotating force of the dicing blade to be separated from an attachment surface of the UV tape. As a size of the fluorescent substance becomes small, a contact surface with the UV tape becomes small so that adhesive strength is degraded. Since the adhesive strength is small, the fluorescent substance cannot overcome the rotating force as being rubbed against the dicing blade, and thus the fluorescent substance is blown outward.

### SUMMARY OF THE INVENTION

The present invention is directed to providing a method of forming a fluorescent substance wafer into an individual fluorescent substance having smooth surfaces and a uniform size. In particular, the present invention is directed to solving a problem in that a wafer is difficult to process to fluorescent substances, having a relatively small size.

According to an aspect of the present invention, there is provided a method of manufacturing a fluorescent substance, which includes forming dicing trenches on one surface of a fluorescent substance wafer along grid-type dicing lines, filling the dicing trench with an adhesive material having fluidity, curing the adhesive material, reducing a thickness of a surface opposite to the one surface on which the dicing trenches are formed to make an integrated form of a plurality of individual fluorescent substances, which are divided along the dicing lines, with the adhesive material connecting therebetween, and removing the adhesive material to remain only the divided individual fluorescent substances.

The adhesive material may be wax, and in the filling of the dicing trench with the adhesive material, the dicing trench may be filled with the wax which is heated to have fluidity, and in the curing of the adhesive material, the wax may be left at room temperature for a predetermined period of time, and in the removing of the adhesive material, a solvent may be applied to the adhesive material to melt the adhesive material.

The adhesive material may be an ultraviolet (UV) curing adhesive material, and in the curing of the adhesive material, the adhesive material may be irradiated with UV rays.

Between the forming of the dicing trench and the filling of the dicing trench, the method may further include grinding the one surface on which the dicing trench is formed to a uniform thickness so as to remove a chipping region formed on the one surface of the wafer in the forming of the dicing trench.

The reducing a thickness of a surface opposite to the one surface on which the dicing trenches are formed may include turning over the wafer in which the dicing trench is filled with the adhesive material to place the wafer coming into contact with an upper surface of the workbench, and grinding an upper surface of the wafer to a uniform thickness over the entire wafer using a surface grinder until the surface grinder reaches the adhesive material.

### BRIEF DESCRIPTION OF THE DRAWINGS

The above and other objects, features and advantages of the present invention will become more apparent to those skilled in the art by describing exemplary embodiments thereof in detail with reference to the accompanying drawings, in which:

FIG. 1 is an overall diagram illustrating a method of manufacturing a fluorescent substance according to one embodiment of the present invention;

FIG. 2 is a diagram illustrating a dicing process in the method of manufacturing a fluorescent substance according to one embodiment of the present invention;

FIG. 3 is a diagram illustrating a grinding process in the method of manufacturing a fluorescent substance according to one embodiment of the present invention;

FIG. 4 is a diagram illustrating a filling result of an adhesive liquid in the method of manufacturing a fluorescent substance according to one embodiment of the present invention;

FIGS. 5 and 6 are diagrams illustrating a grinding process in the method of manufacturing a fluorescent substance according to one embodiment of the present invention;

FIG. 7 is a diagram illustrating a removal result of the adhesive liquid in the method of manufacturing a fluorescent substance according to one embodiment of the present invention; and

FIG. 8 is an overall diagram illustrating a method of manufacturing a fluorescent substance according to the related art.

### DETAILED DESCRIPTION OF EXEMPLARY EMBODIMENTS

Hereinafter, exemplary embodiments of the present invention will be described in detail with reference to the accompanying drawings. The accompanying drawings show exemplary forms of the present invention, which are merely provided to describe the present invention in more detail, and the technical scope of the present invention is not limited thereto.

In addition, regardless of the reference numerals, the same or corresponding components are given the same reference numbers, and duplicate descriptions thereof will be omitted herein. For convenience of description, a size and a shape of each shown component may be exaggerated or reduced.

Further, it should be understood that terms including ordinals such as “a first,” “a second,” and the like may be used herein to describe various components, but the components are not limited to the terms, and these are used only for the purpose of distinguishing one component from another.

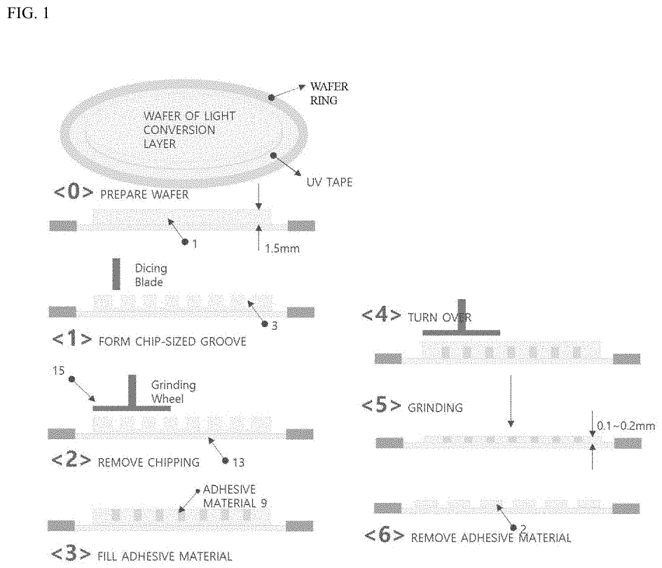

As shown in FIG. 1, in a process <0>, a wafer 1 to be divided into individual fluorescent substances 2 is prepared first. The wafer 1 may be manufactured in a circular shape or a quadrangular shape. It is more efficient to manufacture a wide wafer 1 and divide the wide wafer 1 to manufacture the fluorescent substance 2 in the form of a small chip compared to manufacture a small-sized fluorescent substance 2 in the size of a real product from an initial stage. The above method is used because a size of the commonly used fluorescent substance 2 is relatively small to be processed by hand or machine. The wafer 1 may be obtained by mixing a fluorescent material in a powder state with a glass crystal or a silicone resin, and then applying processing including sintering, compressing, and drying thereto.

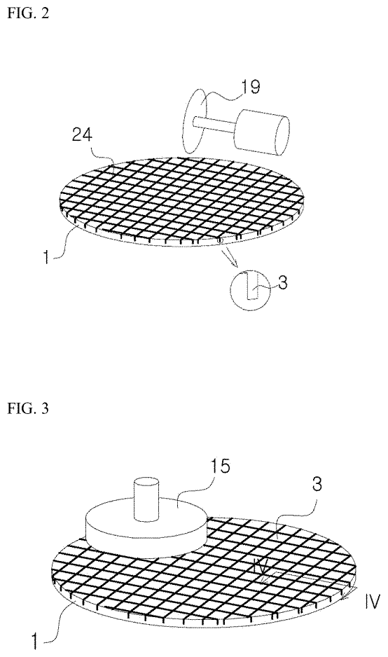

As shown in FIGS. 1 and 2, as a process <1>, dicing trenches 3 are formed in the wafer 1. A grid form is formed by forming a plurality of straight lines at regular intervals along dicing lines 24 using a dicing blade 19 and forming the plurality of dicing lines 24 perpendicular to the straight lines. The dicing trenches 3 may be formed by cutting the wafer 1 like a slicing only to a partial depth without dividing the wafer 1 completely. The wafer 1 is convexly formed between the dicing trenches 3, and the convex portions are to be the individual fluorescent substances 2.

As shown in FIGS. 1 and 3, as a process <2>, a surface on which the dicing trenches 3 of the wafer 1 are formed is ground with a surface grinder 15. Rough grinding is performed to uniformly reduce a thickness of the wafer 1. The above process may be performed by rotating the surface grinder 15 while gradually lowering the surface grinder 15 toward a workbench 13. The grinder 15 has a wide disc-shaped disk, and the disk is rotated to grind a surface of a material. A grinding system may be build using mechanical equipment provided with a support for movably supporting the grinder 15, a support bed on which the wafer 1 is placed, and a controller.

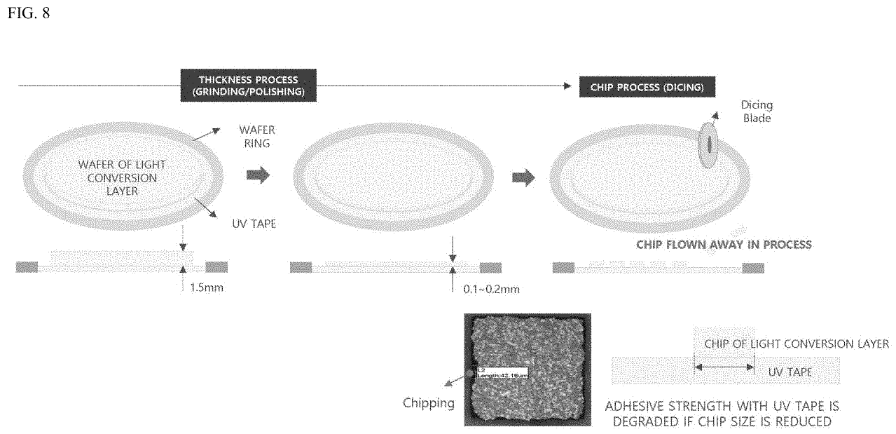

As shown in FIGS. 2 and 8, a chipping phenomenon occurs on the surface of the wafer 1 during the process of scribing the wafer 1 using the dicing blade 19. The wafer 1 is manufactured by mixing several particles with adhesive materials. Therefore, in the process of scribing the surface of the wafer 1 using the dicing blade 19, the materials constituting the wafer 1 are crumbled to form the dicing trench 3, but at the same time, the chipping phenomenon occurs. In the process of forming the dicing trench 3 as in the process <1>, the surface of the wafer 1 is mainly crumbled, and thus the chipping phenomenon mainly occurs on the surface of the wafer 1. Chipping portions may be removed by performing grinding in the process <2>.

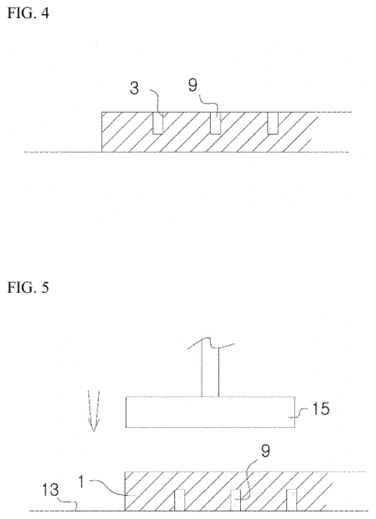

As shown in FIGS. 1 and 4, as a process <3>, the dicing trench 3 is filled with an adhesive material 9. In subsequent processes, until the individual fluorescent substances 2 in the form of a chip are completely separated, the inside of the dicing trench 3 is filled with the adhesive material 9 so that the wafer 1 is supported.

Wax, a UV curable adhesive material, or the like may be applied as the adhesive material 9.

The wax is a material which has a predetermined degree of viscosity and fluidity at a relatively high temperature and is cured and solidified when exposed to a relatively low temperature for a predetermined period of time or more. In the present invention, the process <3> may be performed by applying heat to the wax up to a predetermined temperature to fluidize the wax, applying the fluidized wax to the dicing trench 3, filling the dicing trench 3 with the fluidized wax, and maintaining the fluidized wax at room temperature. When the wax which is heated to have increased fluidity is applied to the dicing trench 3 and the surface of the wafer is polished using a scraper, the surface of the wax may be planarized, like the surface of the wafer 1 as shown in FIG. 4.

When the wax is kept at room temperature and a predetermined period of time elapses, the wax is to be cured. The wax cured the inside of the dicing trench 3 connects between grid-shaped convex portions to be subsequently divided into the individual fluorescent substances 2 chips. Therefore, these convex portions may be connected through the wax.

The UV curable adhesive material is a material which normally has fluidity and is cured when exposed to UV rays. When the UV curable adhesive material is applied to the dicing trench 3 at room temperature and irradiated with UV rays, the UV curable adhesive material is cured. Like the wax, the cured UV curable adhesive material may be planarized using a scraper, and the cured UV-curable adhesive material connects between the grid-shaped convex portions to be subsequently divided into the individual fluorescent substance 2 in the form of a chip. Instead of leaving the cured UV-curable adhesive material at room temperature like the wax, since the curing process is accelerated by emitting UV rays, it is possible to reduce a time required for curing the adhesive material 9 and achieving uniformity in each process.

In the process <3>, the dicing trench 3 is filled with the adhesive material 9, and the adhesive material 9 is cured to strengthen the overall rigidity of the wafer 1 and to connect the portion to be subsequently divided into the individual fluorescent substances 2.

As shown in FIGS. 1, 5, and 6, as a process <4>, the wafer 1 is turned over, and as a process <5>, a grinding operation is performed on a surface of the wafer 1 on which the dicing trench 3 is not formed. The grinding operation is performed on the surface opposite to the surface on which the dicing trench 3 filled with the adhesive material 9 is formed, and thus the thickness of the wafer 1 is gradually reduced. As shown in FIG. 5, the wafer 1 is turned over to direct the portions to which the adhesive material 9 is applied to face down, thereby being placed on the workbench 13, and the surface grinder 15 grinds the surface of the wafer 1. Rough grinding is performed to reduce the thickness of the wafer 1. The above process is continued until the surface of the surface grinder 15 comes into contact with an inner surface of the cured adhesive material 9 while gradually lowering the surface grinder 15 to the workbench 13.

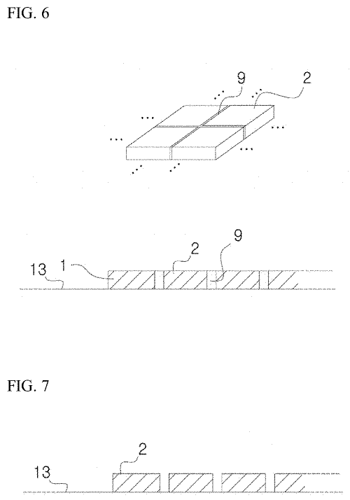

In this way, when the thickness of the wafer 1 is reduced by grinding one surface of the wafer 1, as shown in FIG. 6, it eventually becomes a state in which gaps between the plurality of fluorescent substances 2 are filled with the adhesive materials 9. That is, the wafer 1 is already in a state of being divided into the plurality of fluorescent substance 2, and the adhesive materials 9 connect between the divided fluorescent substances 2, that is, it is in a state in which chips of the plurality of fluorescent substance 2 are embedded in a row between the adhesive materials 9. The above condition may be achieved by performing grinding up to the inner surface of adhesive material 9, but the more grinding may be performed by further lowering the grinder 15. The grinding operation may be performed until the thickness of the wafer 1 reaches a required thickness, that is, ranging from 0.1 mm to 0.2 mm as illustrated in FIG. 1.

Although a force is applied to the fluorescent substances 2 due to the rotating force of the grinder 15 in a lateral direction, since the adhesive materials 9 support the fluorescent substances 2, the fluorescent substances 2 can be maintained in their shapes without being separated. Even though the wafer 1 is manufactured in a very small size, a separation phenomenon of the fluorescent substance 2 does not occur. In addition, when the adhesive material 9 is not applied, a position of the fluorescent substance 2 may be moved, and the position and direction are different for each fluorescent substance 2, thereby performing uneven grinding. However, in the present embodiment, since the fluorescent substance 2 and the adhesive material 9 are bonded as a lump, the above problem does not occur.

Lastly, as shown in FIGS. 1 and 7, as a process <6>, the adhesive material 9 between the fluorescent substances 2 is removed.

If the adhesive material 9 is wax, the adhesive material 9 may be removed by spraying a solvent, such as alcohol, on an area in which the wax is formed. When alcohol is evenly sprayed across the fluorescent substances 2, and after a while, as shown in FIG. 7, the fluorescent substance 2 is separated into individual chips.

If the adhesive material 9 is a UV-curable adhesive material, in order to remove the UV-curable adhesive material, UV rays may be irradiated. Previously, the UV rays are irradiated so as to cure the adhesive material 9, and when the UV rays are irradiated once more in the process <6>, the adhesive material 9 is further cured and completely separated from the fluorescent substance 2. If the workbench is a UV tape, the adhesive material 9 may be removed together when the UV tape is removed.

Since the method of applying a solvent or UV rays is used instead of a physical method, it is possible to prevent damage to the fluorescent substance 2 compared to when the adhesive material 9 is physically removed from the fluorescent substance 2. In addition, it is possible to prevent a portion of the adhesive material 9 from remaining on a side surface of the fluorescent substance 2, thereby preventing the formation of spots or uneven formation on the side surface of the fluorescent substance 2.

Through the above-described process, a small-sized fluorescent substance 2 can be manufactured to have smooth surfaces. That is, the chipping portion on the surface of the wafer 1 formed while forming the dicing trench 3 is removed in the process <2>, After the chipping portion is removed, the smooth dicing trench 3 is filled with the adhesive material 9 in the process <3>, the grinding is performed to separate the wafer 1 into individual fluorescent substances 2, while the fluorescent substance 2 and the adhesive material 9 are integrally formed to prevent separation and shape deformation of the fluorescent substance 2 in the processes <4> and <5>, and only the adhesive material 9 can be removed without damage or deformation of the fluorescent substance 2 in the process <6>.

According to the present invention, by forming a dicing trench on a wafer and then filling the dicing trench with an adhesive material, in a state that individual fluorescent substances are integrally maintained, the wafer can be divided into the individual fluorescent substances by grinding process. Accordingly, it is possible to prevent the fluorescent substances from being flown away from a workbench or from being non-uniformly processed. In other words, even when dicing lines are densely formed to manufacture small fluorescent substances, a surface of a finally obtained fluorescent substance can be kept smooth, and sizes and shapes of all fluorescent substances can be uniformly produced.

As described above, although the embodiments of the present invention have been described, various modifications and changes of the present invention can be achieved by adding, changing, or deleting components within the scope of the present invention by those skilled in the art without departing from the spirit of the present invention described in the appended claims, and these modifications and changes fall within the scope of the present invention.

What is claimed is:

1. A method of manufacturing a fluorescent substance, the method comprising:
forming dicing trenches on one surface of a fluorescent substance wafer along grid-type dicing lines;
filling the dicing trench with an adhesive material having fluidity;
curing the adhesive material;
reducing a thickness of a surface opposite to the one surface on which the dicing trenches are formed to make an integrated form of a plurality of individual fluorescent substances, which are divided along the dicing lines, with the adhesive material connecting therebetween; and
removing the adhesive material to remain only the divided individual fluorescent substances.

2. The method of claim 1, wherein:
the adhesive material is wax;
in the filling of the dicing trench with the adhesive material, the dicing trench is filled with the wax which is heated to have fluidity;
in the curing of the adhesive material, the wax is left at room temperature for a predetermined period of time; and
in the removing of the adhesive material, a solvent is applied to the adhesive material to melt the adhesive material.

3. The method of claim 1, wherein:
the adhesive material is an ultraviolet (UV) curing adhesive material; and
in the curing of the adhesive material, the adhesive material is irradiated with UV rays.

4. The method of claim 1, further comprising, between the forming of the dicing trench and the filling of the dicing trench, grinding the one surface on which the dicing trench is formed to a uniform thickness so as to remove a chipping region formed on the one surface of the wafer in the forming of the dicing trench.

5. The method of claim 1, wherein the reducing a thickness of a surface opposite to the one surface on which the dicing trenches are formed comprises turning over the wafer in which the dicing trench is filled with the adhesive material to place the wafer coming into contact with an upper surface of the workbench, and grinding an upper surface of the wafer to a uniform thickness over the entire wafer using a surface grinder until the surface grinder reaches the adhesive material.
